(19) United States
(12) Patent Application Publication
(10) Pub. No.: US 2022/0194739 A1
(43) Pub. Date: Jun. 23, 2022

(54) ELEVATOR OPERATING PANEL AND OPERATING METHOD THEREFOR

(71) Applicant: Inventio AG, Hergiswil (CH)

(72) Inventor: Pietro Bonomi, Verbania (IT)

(21) Appl. No.: 17/594,623

(22) PCT Filed: Apr. 27, 2020
(86) PCT No.: PCT/EP2020/061630

§ 371 Date: Oct. 25, 2021

(30) Foreign Application Priority Data
Apr. 30, 2019 (EP) 19171961.6

(51) Int. Cl. B66B 1/46; B66B 3/00

(52) U.S. Cl. CPC B66B 1/468; H03K 17/9622; B66B 2201/4684; B66B 3/00

(57) ABSTRACT

A method for operating an elevator and an operating panel for an elevator for carrying out the method, as well as an elevator having such an operating panel, include an operating panel having a plurality of capacitive buttons and a control unit that evaluates a change in capacitance of the capacitive buttons in order to detect an actuation of the button. If an actuation of a first button is detected, the actuation duration of this first button exceeds a predetermined first time period, and an actuation of at least one second button arranged adjacent to the first button is detected, the actuation of the first button is then controlled on the basis of a change in capacitance of the actuated second button such that the control unit cancels the actuation of the first button if the actuation of the second button continues during a predetermined check period.

### FIELD

The present invention relates to a method for operating an elevator and an operating panel for an elevator for carrying out the method, as well as an elevator having such an operating panel or computer program product which implements this method and a computer-readable medium having the computer program product stored thereon.

### BACKGROUND

Elevator systems are used, for example, to transport passengers and/or goods between different floors within a building by means of elevator cars. Operating panels, also called panels, are especially used in elevator systems. An elevator operating panel is known as a COP (Car Operation Panel) inside the elevator car, or as an LOP (Landing Operation Panel) outside the elevator car, which has various buttons for inputting a car call or a landing call. Such an operating panel has to fulfill very many and even partially contradirectional requests. The operating panel should be functionally reliable and it is also expected to be cost-effective. Aesthetics also play an increasingly important role today. The operating panels therefore have to be visually appealing and they should be adaptable to the design of the elevator. Therefore, there is currently a trend for using increasingly more capacitive operating panels, and mechanical buttons are increasingly being replaced with capacitive buttons. So-called capacitive touchscreens find good use in this case. In contrast to a conventional resistive touchscreen, a capacitive touchscreen also operates without pressure. It only needs to be touched for interaction. A change in capacitance or charge of a capacitive button that results from an electrical field which reacts to a touch is detected such that an actuation of a button can be determined.

A disadvantage of capacitive buttons, however, is their unintentional triggering. Mechanical buttons provide haptic resistance, whereas a capacitive button can be triggered unintentionally and without being noticed. An everyday example illustrates this inadequate operating safety: a passenger could, for example, stroke a button on an operating panel with their arm or backpack without noticing, and thus unintentionally select an undesired floor, a door opening (DTO: Door To Open), a door closure (DTS: Door To Shut) or a fault message.

The capacitive buttons also have to be calibrated periodically or in the case that a measured capacitance deviates from a target value or a tolerance range, as a capacitance drift could occur over time due to external influences, e.g. static electricity, humidity or temperature fluctuations. Due to specific requirements for elevators, an elevator has to be reliably controlled by an operating panel. If a capacitive operating panel cannot distinguish between an actuation and an incorrect operation of a function button, a calibration could lead to serious consequences. It is assumed that a passenger presses a door opening button (DTO) of a COP in a sustained manner and thus causes a car which is to depart to wait for someone. If the COP determines that this sustained actuation is a fault, a calibration is carried out. In this case, a critical situation could occur, such as a shaft door being closed unexpectedly despite the DTO button being held down, or the car moving away with an open door. In this case, there would be a risk that passengers could step through the shaft door and fall into the open elevator shaft.

### SUMMARY

It has been recognized that, for future uses, as will be described in greater detail below, there may be a need for, in particular, a capacitive operating panel for an elevator system, in which not only a momentary or sustained actuation is reliably detected and ensured, but unintentional actuations can also be ignored as faults. Furthermore, there may be a need for an elevator system having such an operating panel.

Such a need can be met by the subject matter according to any of the advantageous embodiments that are defined in the following description.

Possible features and advantages of embodiments of the invention can be considered, inter alia and without limiting the invention, to be based upon the concepts and findings described below.

According to a first aspect of the invention, a method is provided for operating an elevator comprising an operating panel, the operating panel having a plurality of capacitive buttons and a control unit which evaluates a change in capacitance of the capacitive buttons in order to detect an actuation of the button. If an actuation of a first button is detected, the actuation duration of this first button exceeds a predetermined first time period, and an actuation of at least one second button arranged adjacent to the first button is detected, the actuation of the first button is then controlled on the basis of a change in capacitance of the actuated second button such that the control unit cancels the actuation of the first button if the actuation of the second button continues during a predetermined check period. The control unit will maintain the actuation of the first button if no change in capacitance of the second button takes place during the check period. An operating panel operated using such a method can meet the above-mentioned existing need for an elevator system, and incorrect operation, which could be triggered by the operating panel, or critical situations can be prevented as far as possible.

A neighboring relationship between the buttons can be configured and changed as required, usually by an authorized person, e.g. a service technician. In this case, two buttons that are directly next to one another are to be understood to be neighbors to one another. Alternatively or in addition to this, a certain number of the buttons in a certain region of the operating panel can be defined as neighbors to one another. One of the buttons can be used as the first and the second button at the same time. Thus, two or more allocations or groupings of the first and second buttons, which may partially overlap or influence one another, can be evaluated at the same time. In this case, a second button, the capacitance of which is changed in the check period, can be evaluated by the control unit as another first button.

According to an advantageous embodiment of the invention, if there are two or more second buttons, the control unit can cancel the activated first button only if the number of second buttons, the capacitance of which has been changed in the check period, exceeds a predetermined limit number.

According to a further advantageous embodiment of the invention, the control unit can cancel the actuation of the first button if the actuation duration of the first button exceeds a predetermined second time period, even if no change in capacitance of the second button took place in the check period. The reason for this is that an unintentional actuation of one or more buttons should usually be either fairly short or unusually long. And a fault for or in the case of a button is usually also a continuous fault, such as a button becoming defective or failing due to an electronic error or contamination. The second time period should thus be significantly longer than the first time period and/or the check period. The first time period and the second time period can run simultaneously with the same start time, one after the other or independently of one another.

According to another advantageous embodiment of the invention, the control unit can generate an alarm signal by means of an alarm indicator if the control unit cancels the actuated first button after the second time period has elapsed. The alarm indicator can be integrated into the operating panel or arranged as a separate device from the elevator. Since the second time period is usually defined to be sufficiently long, the control unit can assume that an unusually continuously actuated button is to be regarded as a fault or an error. In order to ensure safety at all times, even in the case of unusual use or misuse of the operating panel, a passenger, who may still be operating the operating panel, is informed of this cancellation of the button. The alarm signal could be an optical, acoustic and/or textual signal.

According to a further advantageous embodiment of the invention, the capacitances of the capacitive buttons are calibrated by the control unit to their predetermined target capacitance values when none of the buttons are actuated. Such a calibration can be carried out periodically and automatically after a predefined period of time. This means that the buttons on the operating panel may only be calibrated if either none of the buttons are confirmed or a fault has been detected. A capacitance drift that could possibly or potentially occur on a capacitive button can thus be compensated, as a result of which the control unit can precisely determine and evaluate changes in capacitance of the buttons.

Furthermore, the operating panel is configured to communicate wirelessly with an external control means (e.g. computer or server). This makes it possible for the data connection between the operating panel and the external control means to be established in a simple manner without, for example, the need to lay electrical lines. Different technologies can be used for wireless communication, depending on whether the external control means is arranged relatively close to the operating panel or the elevator, i.e., is located in the same building, for example, or whether the external control means is arranged far away. For example, a local radio network (e.g. WLAN/WiFi) can be used at short distances. This information can be passed to the external control means via the data connection. The external control means could have been programmed in advance with criteria, on the basis of which the external control means can make an assessment. In particular, the generated alarm signal can be forwarded to a main controller of the elevator and/or a remote control center. That is to say, depending on how the control unit evaluates a criticality of this fault, possibly using other determined parameters, various measures can be taken to either put the elevator out of operation or to temporarily restrict only some functions, such as turning off the functions of DTO and DTS buttons.

According to a second aspect of the invention, an operating panel for an elevator for carrying out a method according to an embodiment of the first aspect of the invention is proposed.

According to a third aspect of the invention, an elevator comprising an operating panel according to an embodiment of the second aspect is provided, the operating panel being arranged as a Car Operation Panel (COP) or Landing Operation Panel (LOP) of the elevator.

According to a fourth aspect of the invention, a computer program product is provided which contains computer-readable instructions which, when executed by a control device of an elevator operating panel, instruct to carry out a method according to an embodiment of the first aspect.

According to a fifth aspect of the invention, a computer-readable medium is proposed which has a computer program product according to an embodiment of the fourth aspect stored thereon.

It should be noted that some of the possible features and advantages of the invention are described herein with reference to different embodiments of the operating panel according to the invention and the method according to the invention. A person skilled in the art recognizes that the features can be combined, transferred, adapted, or exchanged in a suitable manner in order to arrive at further embodiments of the invention.

An advantageous embodiment of the invention will be described below with reference to the enclosed drawings, with neither the drawings nor the description being intended to be interpreted as limiting the invention. The drawings are merely schematic and not true to scale. The same reference signs indicate the same or equivalent features.

### DESCRIPTION OF THE DRAWINGS

In the drawings:

FIG. 1 is a schematic view of an operating panel according to the invention for an elevator, and

FIG. 2 shows a flow chart for an embodiment for determining an actuation of a capacitive button on the operating panel.

### DETAILED DESCRIPTION

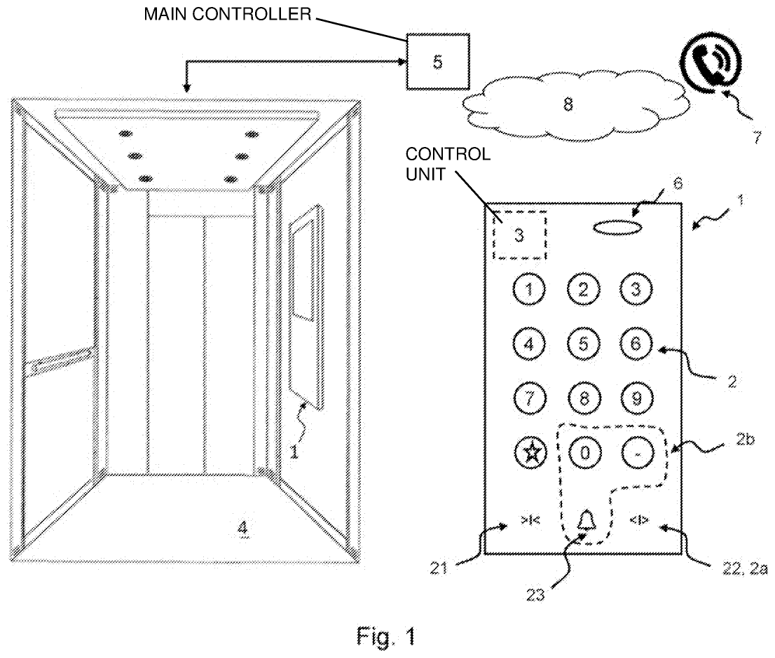

FIG. 1 shows an operating panel 1 according to the invention, e.g. a COP for an elevator 4. The operating panel 1 is a capacitive panel and comprises a plurality of capacitive buttons 2 and a control unit 3. Each button 2 has a different capacitance in its actuated (or activated) switching state or idle state (or non-activated switching state). For this reason, the control unit 3 can effectively perceive actuations of different buttons 2 and distinguish them from one another by monitoring a change in capacitance of each button 2.

For a better view of a button configuration of such buttons 2, the operating panel 1 is shown especially enlarged at the bottom left in the figure. The button configuration is a standard numeric keypad having two function buttons for temporary functions and a fault message button 23, the two function buttons being labeled with a character «-» and «*», respectively. The control unit 3, which is integrated into the operating panel 1 or is arranged behind the panel, for example, is shown by a dashed box.

It is possible for at least one first button 2a and at least one second button 2b, which is arranged adjacent to the first button 2a, to be provided as the buttons 2. A button 2 is detected by the control unit 3 as a first button 2a by means of a manual actuation. At the same time, at least one second button 2b, which is an adjacent button to the first button 2a, is identified and monitored by the control unit 3. If there are further buttons which are not adjacent buttons 2b, such further buttons can remain out of consideration in the evaluation or control of the first button 2a. A button 2 can be detected at the same time both as a first button 2a and as a second button 2b for one or more other buttons which is or are considered to be another first button. In this case, all of the first buttons 2a can be evaluated at the same time and depending on their respective adjacent second buttons 2b. If, for example, a door opening button (DTO) 22 is pressed, this button is then considered to be a first button 2a, while the fault message button 23, the ground floor destination call button «0» and button «-» are the second buttons 2b. In FIG. 1, such second buttons 2b are surrounded by a dash-dotted line so as to be recognizable. In another example, if the door lock button (DTS) 21 is a first button 2a, button «*», the fault message button 23 and the first floor destination call button «0» are correspondingly the second buttons 2b. Analogously, it can be deduced in a similar manner that when the fifth floor destination call button «5», which acts as the first button 2a, is actuated, buttons «1», «2», «3», «4», «6», «7», «8» and «9» are then the second buttons 2b.

The operating panel 1 also comprises an alarm indicator 6. If the control unit 3 deactivates or cancels a first button 2a which is actuated in a sustained manner or detects it as a fault, the alarm indicator 6 can generate an alarm signal. This alarm signal can be forwarded to a main controller 5 of the elevator 4 and to a remote control center 7 via a network 8. In this case, the main controller 6 can interrupt the operation of the elevator 4 or, after evaluation of the control unit 5, temporarily block only some functions, such as preventing the door from being controlled by the DTS/DTO button.

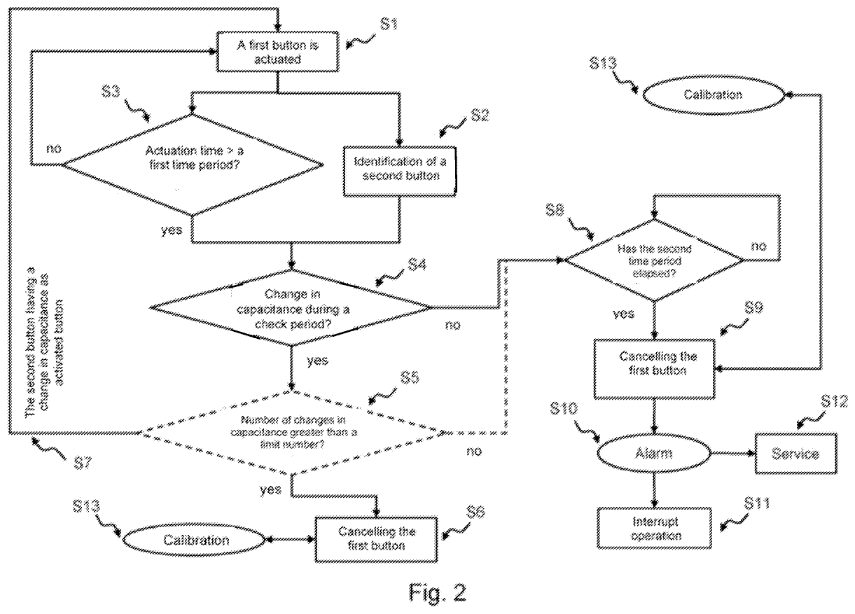

FIG. 2 shows the functions of an operating panel 1 according to FIG. 1 or a method for operating an elevator 4 by means of this operating panel 1, the corresponding method steps being illustrated by a flowchart in the following steps S1 to S14.

S1: A button 2 is detected as an actuated first button 2a.

S2: The control unit 3 detects this actuation of the first button 2a and at the same time identifies at least one button adjacent to the first button 2a as the second button 2b.

S3: The control unit 3 checks whether the actuation duration of the first button 2a exceeds a first time period (for example one or two seconds from the actuation of the button). If this is not the case, this button 2 remains activated as a normal button.

S4: The control unit 3 checks whether the capacitance of one of the second buttons 2b is changed during a second predetermined time period.

S5: If at least one change in capacitance took place in the second time period, it is further checked how many second buttons 2b there are in which the capacitance has been changed. Since step S5 is optional, this block is shown by a dash-dotted line.

S6: If the number of such second buttons 2b exceeds a predetermined limit number, the first button 2a is canceled. If this is not the case, there is a shift to method step S9.

S7: Regardless of whether the limit number is exceeded or not, an evaluation of the second buttons 2b, at which a change in capacitance is determined, begins again from step S1, as for a new activated button.

S8: If no change in capacitance is determined in step S4 or the number of second buttons 2b for which a change in capacitance is determined does not exceed the limit number (step S5), control unit 3 will further check whether the activation duration of the first button 2a exceeds a second predetermined time period.

S9: If this is the case, the first button 2a is canceled by the control unit 3 such that a sustained activation of a button, possibly triggered by a fault or incorrect operation, can be prevented. If the first button 2a is a DTO button 22, for example, this can mean that the shaft door and car door are nevertheless closed.

S10: After deactivation, the control unit 3 generates, for example, an acoustic alarm signal by means of an alarm indicator 6 in order to notify a passenger or service personnel of the fault or cancellation.

S11: Thereafter, or at the same time, the operation of the elevator 4 can be interrupted.

S12: The generated alarm signal is forwarded to a main controller 5 of the elevator 4 and/or to a remote control center 7.

S13: A calibration can be carried out after the cancellation of the first buttons 2a if no button 2 has been actuated or a fault has been detected.

Finally, it should be noted that terms such as “comprising,” “having,” etc. do not preclude other elements or steps, and terms such as “a” or “an” do not preclude a plurality. Furthermore, it should be noted that features or steps which have been described with reference to one of the above embodiments may also be used in combination with other features or steps of other embodiments described above.

In accordance with the provisions of the patent statutes, the present invention has been described in what is considered to represent its preferred embodiment. However, it should be noted that the invention can be practiced otherwise than as specifically illustrated and described without departing from its spirit or scope.

1-15. (canceled)

16. A method for operating an elevator having an operating panel, the operating panel having a plurality of buttons being capacitive buttons and a control unit that evaluates a change in capacitance of the buttons to detect an actuation of each of the buttons, the method comprising the steps of:
when an actuation of a first button of the plurality of buttons is detected by the control unit, the control unit checks whether an actuation duration of the first button exceeds a predetermined first time period;
when an actuation of at least one second button of the plurality of buttons arranged adjacent to the first button is detected, the control unit controls the actuation of the first button on a basis of a change in capacitance of the actuated at least one second button such that the control unit cancels the actuation of the first button when the actuation of the at least one second button continues during a predetermined check period.

17. The method according to claim 16 wherein the control unit cancels the actuation of the first button when at least two second buttons are actuated and a number of the actuated second buttons, a capacitance of each of the actuated second buttons changing in the predetermined check period, exceeds a predetermined limit number.

18. The method according to claim 16 wherein when another button of the plurality of buttons is actuated at a same time as the first button and the at least one second button are actuated, a capacitance of the another button changing in the predetermined check period, the another button is evaluated by the control unit as another first button.

19. The method according to claim 16 wherein the control unit cancels the actuation of the first button when an actuation duration of the first button exceeds a predetermined second time period.

20. The method according to claim 19 including generating an alarm signal from an alarm indicator when the actuation of the first button is canceled by the control unit after the predetermined second time period has elapsed.

21. The method according to claim 20 including forwarding the alarm signal to at least one of a main controller and a remote control center of the elevator.

22. The method according to claim 16 including calibrating the plurality of buttons by the control unit to predetermined target capacitance values when none of the buttons are actuated.

23. An operating panel for an elevator for performing the method according to claim 16, the operating panel comprising:
the plurality of buttons being capacitive buttons;
the control unit;
wherein the control unit adapted to detect an actuation and an actuation duration of each of the buttons of the plurality of buttons by determining a change in capacitance of each of the buttons; and
when an actuation of a first button of the plurality of buttons is detected by the control unit, an actuation duration of the first button exceeds a predetermined first time period, and an actuation of at least one second button of the plurality of buttons is detected, the at least one second button being arranged adjacent to the first button, the control unit controls the actuation of the first button on a basis of a change in capacitance of the actuated second button such that the control unit cancels the actuation of the first button when the actuation of the second button continues during a predetermined check period.

24. The operating panel according to claim 23 wherein the control unit is adapted to cancel the actuation of the first button when a number of second buttons of the plurality, including the at least one second button, have a change in capacitance in the predetermined check period exceeds a predetermined limit number.

25. The operating panel according to claim 23 wherein the control unit is adapted to cancel the actuation of the first button when the actuation duration of the first button exceeds a predetermined second time period.

26. The operating panel according to claim 25 wherein the control unit generates an alarm signal by an alarm indicator when the control unit cancels the actuation of the first button after the predetermined second time period has elapsed.

27. The operating panel according to claim 23 wherein the control unit is adapted to calibrate the buttons of the plurality of buttons to predetermined target capacitance values when none of the buttons are actuated.

28. An elevator comprising an operating panel according to claim 23 operated as a car operation panel in an elevator car or a landing operation panel of the elevator.

29. A computer program product comprising computer-readable instructions that, when the instructions are executed by a control device of an operating panel of an elevator, instruct the control device to carry out or control the method steps according to claim 16.

30. A non-transitory computer-readable medium having the computer program product according to claim 29 stored thereon.

31. A method for operating an elevator having an operating panel, the operating panel having a plurality of buttons being capacitive buttons and a control unit that evaluates a change in capacitance of the buttons to detect an actuation of each of the buttons, the method comprising the steps of:
detecting an actuation and an associated actuation duration of a first button of the plurality of buttons with the control unit;
identifying a second button of the plurality of buttons being adjacent to the first button;
checking by the control unit whether the actuation duration of the first button exceeds a predetermined first time period wherein the first button remains activated when the actuation duration does not exceed the predetermined first time period;
checking by the control unit whether a capacitance of the second button changes during a second predetermined time period;
the control unit cancelling the actuation of the first button when the actuation of the at least one second button continues during a predetermined check period.
when there is no change in capacitance of the second button during the predetermined second time period, checking by the control unit whether the activation duration of the first button exceeds the second predetermined time period;
cancelling the actuation of the first button by the control unit when the activation duration of the first button exceeds the second predetermined time period to prevent a sustained activation of the first button;
after the activation of the first button is canceled, generating by the control unit an alarm signal from an alarm indicator to notify at least one of a passenger and service personnel of the cancellation.

32. The method according to claim 31 including the following steps:
when the capacitance of the second button changed in the second time period, checking by the control unit whether any other second buttons changed capacitance in the second time period; and
when a number of the second buttons that changed capacitance in the second time period exceeds a predetermined limit number, the control unit cancels the activation of the first button.
